(19) United States
(12) Patent Application Publication
(10) Pub. No.: US 2026/0018414 A1
(43) Pub. Date: Jan. 15, 2026

(54) SEMICONDUCTOR DEVICE MANUFACTURING METHOD

(71) Applicant: JUSUNG ENGINEERING CO., LTD., Gwangju-si, Gyeonggi-do (KR)

(72) Inventors: Won Tae CHO, Yongin-si, Gyeonggi-do (KR); Chul Joo HWANG, Yongin-si, Gyeonggi-do (KR)

(21) Appl. No.: 18/992,562

(22) PCT Filed: Jul. 7, 2023
(86) PCT No.: PCT/KR2023/009642

§ 371 Date: Jan. 8, 2025

(30) Foreign Application Priority Data
Jul. 18, 2022 (KR) 10-2022-0088427
Jul. 19, 2022 (KR) 10-2022-0088800
Apr. 6, 2023 (KR) 10-2023-0045260

(51) Int. Cl. H01L 21/02; H01L 21/56; H10D 30/01; H10H 20/01

(52) U.S. Cl. CPC H01L 21/0262; H01L 21/02381; H01L 21/0254; H01L 21/02546; H01L 21/02576; H01L 21/02579; H01L 21/56; H10D 30/031; H10H 20/01335

(57) ABSTRACT

The present invention relates to a layer formation method and, more specifically, to a semiconductor device manufacturing method for forming a semiconductor device through a low-temperature process. The layer formation method according to an embodiment of the present invention is a method for manufacturing a semiconductor device which comprises a silicon substrate containing germanium (Ge) or a substrate on which a silicon layer containing germanium (Ge) is formed, and which comprises an undoped gallium nitride (GaN) layer, an N-type gallium nitride (GaN) layer, an active layer and a P-type gallium nitride (GaN) layer, wherein a step of forming at least one gallium nitride layer from among the undoped gallium nitride (GaN) layer, the N-type gallium nitride (GaN) layer, the active layer and the P-type gallium nitride (GaN) layer comprises the steps of: a) sequentially supplying a gallium (Ga) precursor and a nitrogen (N2) precursor at 500° C. or lower, thereby forming a gallium nitride (GaN) layer on the substrate; and b) exposing the gallium nitride (GaN) layer to a hydrogen-containing plasma, and steps a) and b) are repeated multiple times.

### TECHNICAL FIELD

The present invention relates to a method of manufacturing a semiconductor device.

### BACKGROUND ART

Liquid Crystal Display (LCD) and Organic Light Emitting Diode (OLED) displays are widely used as display devices. Recently, technology for manufacturing high-resolution display devices using micro-sized LED devices (Micro Light Emitting Diode Devices) has been in the spotlight.

A conventional micro LED is a self-luminous display equipped with a micro LED in μm at the pixel position of the driving substrate and has advantages such as high luminance, high power efficiency, long life, and various form factors. However, the transfer process of positioning micro LEDs in μm at the pixel position of the driving substrate is carried out by the pick and place method, which is difficult to ensure productivity and economic feasibility. In particular, there is a need for other methods to manufacture a large-area micro LED display.

In addition, the Metal Organic Chemical Vapor Deposition (MOCVD) method is generally used to form the gallium nitride layer. In such an MOCVD method, a gallium nitride layer is deposited while the temperature of the substrate is adjusted to a high temperature of about 1200° C. That is, when the substrate is maintained at a high temperature of about 1200° C., a gallium nitride layer may be deposited on the substrate.

However, as the gallium nitride layer is formed while the substrate is heated to a high temperature, the substrate or the layer formed on the substrate may be damaged. This acts as a factor that degrades or causes defects in the light emission of micro-LEDs, and in particular, there was a problem that greatly reduced the quality and reliability of display devices demanding stable switching operations.

### DISCLOSURE

### Technical Problem

The present invention is devised to solve the above-described problem and is for providing a manufacturing method that can form a gallium nitride layer and a gallium arsenide layer at low temperatures by atomic layer deposition (ALD) method.

### Technical Solution

To accomplish the above-described objects, an embodiment of the present invention provides a method of manufacturing a semiconductor device including a process of forming at least one gallium nitride layer among an undoped gallium nitride layer, an N-type gallium nitride layer, an active layer, and a P-type gallium nitride layer on a silicon substrate containing germanium or a substrate on which a silicon layer containing germanium is formed, the process of forming at least one gallium nitride layer comprises: a) sequentially supplying a gallium precursor and a nitrogen precursor at 500° C. or less to form a gallium nitride layer on the silicon substrate or the substrate, and b) exposing the gallium nitride layer to hydrogen-containing plasma, wherein the a) and the b) are repeated multiple times.

Another embodiment of the present invention provides a method of manufacturing a semiconductor device including a process of forming a gallium nitride layer on a silicon substrate containing germanium or a substrate on which a silicon layer containing germanium is formed, the process of forming the gallium nitride layer comprises sequentially supplying a gallium precursor and a nitrogen precursor into a chamber, and wherein the sequentially supplying a gallium precursor and a nitrogen precursor in a chamber comprises a) flowing the gallium precursor into the chamber at 500° C. or less through a gas injector, and b) flowing the nitrogen precursor through the gas injector to form the gallium nitride on the silicon substrate or the substrate.

Another embodiment of the present invention provides a method of manufacturing a semiconductor device including a process of forming at least one gallium nitride layer among an undoped gallium nitride layer, an N-type gallium nitride layer, an active layer, and a P-type gallium nitride layer on a silicon substrate containing germanium or a substrate on which a silicon layer containing germanium is formed, the process of forming at least one gallium nitride layer comprises sequentially supplying a gallium precursor and a nitrogen precursor at 500° C. or less to form a gallium nitride layer on the silicon substrate or the substrate, wherein plasma is generated when supplying the nitrogen precursor.

The method further comprises exposing the gallium nitride layer to hydrogen-containing plasma after forming the gallium nitride layer.

The process of forming the N-type gallium nitride layer further comprises supplying a silicon precursor, wherein the process of forming the active layer further comprises supplying an indium precursor, and wherein the process of forming the P-type gallium nitride layer further comprises supplying a magnesium precursor.

The method further comprises generating hydrogen-containing plasma between supplying the gallium precursor and supplying the nitrogen precursor.

The method further comprises exposing the silicon substrate or the substrate to a gas containing at least one of fluorine and chlorine to remove oxide and impurities on the silicon substrate or the substrate, before supplying the gallium precursor.

The removing oxide and impurities on the silicon substrate or the substrate is performed in a same chamber or system as a chamber or system for forming the gallium nitride layer.

Another embodiment of the present invention provides a method of manufacturing a semiconductor device including a process of forming at least one gallium arsenide layer among an undoped gallium arsenide layer, an N-type gallium arsenide layer, an active layer, and a P-type gallium arsenide layer on a silicon substrate containing germanium or a substrate on which a silicon layer containing germanium is formed, the process of forming at least one gallium arsenide layer comprises: a) sequentially supplying i) a gallium precursor and ii) an arsenide precursor at 500° C. or less to form a gallium arsenide layer on the silicon substrate or the substrate, and b) exposing the gallium arsenide layer to hydrogen-containing plasma, wherein the a) and the b) are repeated multiple times.

Another embodiment of the present invention provides a method of manufacturing a semiconductor device including a process of forming an arsenide layer on a silicon substrate containing germanium or a substrate on which a silicon layer containing germanium is formed, the process of forming the gallium arsenide layer comprises sequentially supplying a gallium precursor and an arsenide precursor into a chamber, and wherein the sequentially supplying a gallium precursor and an arsenide precursor into a chamber comprises a) flowing the gallium precursor into the chamber at 500° C. or less through a gas injector, and b) flowing the arsenide precursor through the gas injector to form the gallium arsenide layer on the silicon substrate or the substrate.

Another embodiment of the present invention provides a method of manufacturing a semiconductor device including a process of forming at least one gallium arsenide layer among an undoped gallium arsenide layer, an N-type gallium arsenide layer, an active layer, and a P-type gallium arsenide layer on a silicon substrate containing germanium or a substrate on which a silicon layer containing germanium is formed, the process of forming at least one gallium arsenide layer comprises sequentially supplying a gallium precursor and an arsenide precursor at 500° C. or less to form a gallium arsenide layer on the silicon substrate or the substrate, wherein plasma is generated when supplying the arsenide precursor.

The method further comprises exposing the gallium arsenide layer to hydrogen-containing plasma after forming the gallium arsenide layer.

The process of forming the N-type gallium arsenide layer further comprises supplying a silicon precursor, wherein the process of forming the active layer further comprises supplying an indium precursor, and wherein the process of forming the P-type gallium arsenide layer further comprises supplying a magnesium precursor.

The method further comprises generating hydrogen-containing plasma between supplying the gallium precursor and supplying the arsenide precursor.

The method further comprises exposing the silicon substrate or the substrate to a gas containing at least one of fluorine and chlorine to remove oxide and impurities on the silicon substrate or the substrate, before supplying the gallium precursor.

The removing oxide and impurities on the silicon substrate or the substrate is performed in a same chamber or system as a chamber or system for forming the gallium arsenide layer.

The method further comprises forming an encapsulation layer to prevent moisture or oxygen from penetrating through the silicon substrate or the substrate.

The method further comprises forming a pure silicon layer on the silicon substrate or the substrate.

Another embodiment of the present invention provides a method of manufacturing a semiconductor device comprising loading at least one substrate on a substrate support in an atomic layer deposition chamber including a gas injector, the at least one substrate including a silicon substrate containing germanium or a substrate on which a silicon layer containing germanium is formed; maintaining the substrate support at 500° C. or less; a) flowing a gallium precursor into the atomic layer deposition chamber through the gas injector; b) flowing a purge gas for purging the gallium precursor into the atomic layer deposition chamber; c) flowing a nitrogen precursor or an arsenide precursor into the atomic layer deposition chamber through the gas injector to form the gallium nitride layer or the gallium arsenide layer on the at least one substrate; and d) flowing hydrogen-containing gas into the atomic layer deposition chamber through the gas injector to generate hydrogen plasma, wherein the a) to the d) are repeated multiple times.

### Advantageous Effect

According to the present invention, the following effects may be realized.

According to an embodiment of the present invention, a gallium nitride layer and a gallium arsenide layer are formed by a low temperature process, thereby preventing a semiconductor device from being damaged by high temperature heat. In addition, the transfer process of the substrate for forming the gallium nitride layer and the gallium arsenide layer can be omitted, thereby reducing the manufacturing time and manufacturing cost of the display device.

### DESCRIPTION OF DRAWINGS

FIG. 1 is a diagram illustrating a semiconductor device structure according to an embodiment of the present invention.

FIG. 2 is a diagram illustrating a semiconductor device structure according to another embodiment of the present invention.

FIG. 3 is a diagram illustrating a method of manufacturing a semiconductor device according to another embodiment of the present invention.

FIG. 4 is a diagram illustrating a semiconductor device structure according to an embodiment of FIG. 3.

FIG. 5 is a diagram illustrating an apparatus structure according to an embodiment of the present invention.

### MODE FOR INVENTION

Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this invention will be thorough and complete, and will fully convey the scope of the present invention to those skilled in the art. Furthermore, the present invention is only defined by scopes of claims.

A shape, a size, a ratio, an angle, and a number disclosed in the drawings for describing embodiments of the present invention are merely an example, and thus, the present invention is not limited to the illustrated details. Like reference numerals refer to like elements throughout. In the following description, when the detailed description of the relevant known technology is determined to unnecessarily obscure the important point of the present invention, the detailed description will be omitted. In a case where ‘comprise’, ‘have’, and ‘include’ described in the present specification are used, another part may be added unless ‘only˜’ is used. The terms of a singular form may include plural forms unless referred to the contrary.

In construing an element, the element is construed as including an error range although there is no explicit description.

In describing a position relationship, for example, when a position relation between two parts is described as ‘on˜’, ‘over˜’, ‘under˜’, and ‘next˜’, one or more other parts may be disposed between the two parts unless ‘just’ or ‘direct’ is used.

In describing a time relationship, for example, when the temporal order is described as ‘after˜’, ‘subsequent˜’, ‘next˜’, and ‘before˜’, a case which is not continuous may be included unless ‘just’ or ‘direct’ is used.

It will be understood that, although the terms “first”, “second”, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present invention may be partially or overall coupled to or combined with each other, and may be variously inter-operated with each other and driven technically as those skilled in the art can sufficiently understand. The embodiments of the present invention may be carried out independently from each other, or may be carried out together in co-dependent relationship.

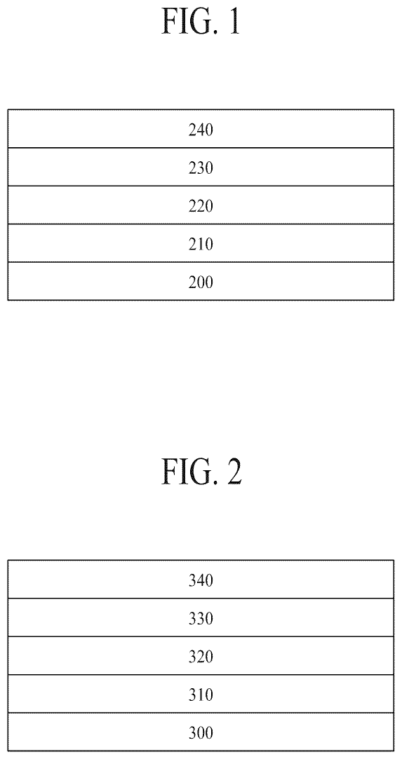

Hereinafter, a semiconductor device structure and a method of manufacturing the same according to the present invention will be described in detail with reference to FIG. 1.

FIG. 1 is a diagram schematically showing a semiconductor device structure such as a green LED or a blue LED according to an embodiment of the present invention.

The semiconductor device structure according to an embodiment of the present invention may include a substrate 200, an undoped gallium nitride (Undoped GaN) layer 210, an N-type gallium nitride (N-type GaN) layer 220, an active layer 230, and a P-type gallium nitride (P-type GaN) layer 240. The semiconductor device structure may include at least one material among InN, GaN, AlN, InP, InAs, InSb, GaAs, and GaSb, and the above materials may be included in different ratios.

An encapsulation layer may be additionally formed on at least one of a lower portion and an upper portion of the semiconductor device structure of FIG. 1.

The substrate 200 may be a silicon substrate containing germanium (Ge) or a substrate on which a silicon layer containing germanium (Ge) is formed.

The method of manufacturing the semiconductor device structure of FIG. 1 may include a process of forming at least one of the undoped gallium nitride (Undoped GaN) layer 210, the N-type gallium nitride (N-type GaN) layer 220, the active layer 230, and the P-type gallium nitride (P-type GaN) layer 240.

The process of forming the gallium nitride layer, in particular, the process of forming the undoped gallium nitride layer 210 may include a) forming a gallium nitride layer on the substrate 200 by sequentially supplying a gallium (Ga) precursor and a nitrogen (N₂) precursor at 500° C. or less. Thereafter, b) exposing the gallium nitride (GaN) layer to hydrogen-containing plasma may be further included. The plasma gas may contain hydrogen gas, and an inert gas, for example, a gas such as helium (He) and argon (Ar), may be used as the plasma gas, and preferably, hydrogen gas may be used as the plasma gas. By exposing the gallium nitride (GaN) layer to a hydrogen-containing plasma, impurities present in the gallium nitride (GaN) layer can be removed and the film quality can be improved.

A process of forming a hydrogen-containing plasma between the process of supplying the gallium (Ga) precursor and the process of supplying the nitrogen (N₂) precursor can be further added. In this case, since the gallium nitride (GaN) layer is obtained by removing impurities in the gallium (Ga) precursor adsorbed on the substrate 200 by the plasma, the film quality of the gallium nitride (GaN) layer can be improved. Helium (He) and argon (Ar) may be used as the plasma gas in this case in addition to hydrogen gas.

Plasma may also be formed when supplying the nitrogen (N₂) precursor. In addition, a step of forming an additional pure silicon layer may be added between the silicon substrate containing germanium (Ge) or the substrate with the silicon layer containing germanium (Ge) and a gallium nitride (GaN) layer. The step of forming the pure silicon layer may include an epitaxy growth (Epi) method of silicon (Si).

Steps a) to b) may be repeated multiple times. Only step a) may be repeated, or only step b) may be repeated.

The forming of the N-type gallium nitride (N-type GaN) layer 220 may further include supplying a silicon (Si) precursor in addition to the steps a) and b), and the forming of the active layer 230 may further include supplying an indium (In) precursor in addition to the steps a) and b), and the forming of the P-type gallium nitride (P-type GaN) layer 240 may further include supplying a magnesium (Mg) precursor.

A gallium nitride (GaN) layer may be formed on the substrate 200 by sequentially supplying the gallium (Ga) precursor and the nitrogen (N₂) precursor. This may be performed using atomic layer deposition (ALD), and specifically, the process of forming the gallium nitride (GaN) layer may include a) flowing a gallium (Ga)-containing precursor into a chamber through a gas injector, and b) flowing a nitrogen (N₂)-containing precursor into the chamber through the gas injector.

In order to prevent moisture or oxygen from penetrating through the substrate 200, an encapsulation layer may be formed on the substrate 200, for example, under the substrate 200.

In addition, after the process of forming the gallium nitride (GaN) layer, an encapsulation layer can be additionally formed on the gallium nitride layer to prevent moisture or oxygen penetration.

A step of removing oxide and impurities on the substrate 200 may be added before the process of supplying the gallium (Ga) precursor. The step of removing oxide and impurities on the substrate 200 includes exposing the substrate 200 to a gas containing at least one of fluorine F and chlorine Cl. At this time, the step of removing the oxide and impurities on the substrate 200 may be performed in the same chamber or system as the chamber or system for forming the gallium nitride layer.

FIG. 2 is a diagram illustrating a semiconductor device structure such as a red LED according to another embodiment of the present invention.

The semiconductor device structure according to FIG. 2 may include a substrate 300, an undoped gallium arsenide (Undoped GaAs) layer 310, an N-type gallium arsenide (N-type GaAs) layer 320, an active layer 330, and a P-type gallium arsenide (P-type GaAs) layer 340. The semiconductor device structure may include at least one material among InN, GaN, AlN, InP, InAs, InSb, GaAs, and GaSb, and the above materials may be included in different ratios.

The substrate 300 may be a silicon substrate containing germanium (Ge) or a substrate on which a silicon layer containing germanium (Ge) is formed.

The semiconductor device may be manufactured by forming an undoped gallium arsenide (Undoped GaAs) layer 310, an N-type gallium arsenide (N-type GaAs) layer 320, an active layer (330), and a P-type gallium arsenide (P-type GaAs) layer 340 on the substrate (300).

The process of forming at least one of the undoped GaAs layer 310, the N-type GaAs layer 320, the active layer 330, and the P-type GaAs layer 340 may include c) forming a gallium arsenide (GaAs) layer on the substrate 300 by sequentially supplying a gallium precursor (Ga) and an arsenide precursor (As) at 500° C. or less, and d) exposing the gallium arsenide (GaAs) layer to hydrogen-containing plasma. Steps c) to d) may be repeated multiple times.

In addition, a step of forming an additional pure silicon layer may be added between the silicon substrate containing germanium (Ge) or the substrate with a silicon layer containing germanium (Ge) and a gallium arsenide (GaAs) layer. The step of forming the pure silicon layer may include an epitaxy growth (Epi) method of silicon (Si).

The forming of the N-type gallium arsenide (N-type GaAs) layer 320 may further include supplying a silicon (Si) precursor in addition to the steps c) and d), and the forming of the active layer 330 may further include supplying an indium (In) precursor in addition to the steps c) and d), and the forming of the P-type gallium arsenide (P-type GaAs) layer 340 may further include supplying a magnesium (Mg) precursor.

In addition, the process of sequentially supplying the gallium (Ga) precursor and the arsenide (As) precursor to form the undoped gallium arsenide (GaAs) layer (310) on the substrate 300 may include a) flowing a gallium (Ga)-containing precursor into a chamber through a gas injector, and b) flowing an arsenide (As)-containing precursor into the chamber through the gas injector.

By exposing the gallium arsenide (GaAs) layer to a hydrogen-containing plasma, impurities present in the gallium arsenide (GaAs) layer can be removed and the film quality can be improved.

A process of forming a hydrogen-containing plasma between the process of supplying the gallium (Ga) precursor and the process of supplying the arsenide (As) precursor may be further added. In this case, since the gallium arsenide (GaAs) layer is obtained by removing impurities in the gallium (Ga) precursor adsorbed on the substrate 300 by the plasma, the film quality of the gallium arsenide (GaAs) layer can be improved. Helium (He) and argon (Ar) may be used as the plasma gas in this case in addition to hydrogen gas.

In addition, plasma may be formed when supplying the arsenide (As) precursor.

An encapsulation layer may be formed on the substrate 300 to prevent moisture or oxygen from penetrating through the substrate 300. In addition, after the step of forming the gallium arsenide (GaAs) layer, an encapsulation layer to prevent moisture or oxygen penetration may be additionally performed on the gallium arsenide layer.

A step of removing oxide and impurities on the substrate 300 may be added before the process of supplying the gallium (Ga) precursor. The step of removing oxide and impurities on the substrate 300 includes exposing the substrate 300 to a gas containing at least one of fluorine F and chlorine Cl. At this time, the step of removing the oxide and impurities on the substrate 300 may be performed in the same chamber or system as the chamber or system for forming the gallium arsenide layer.

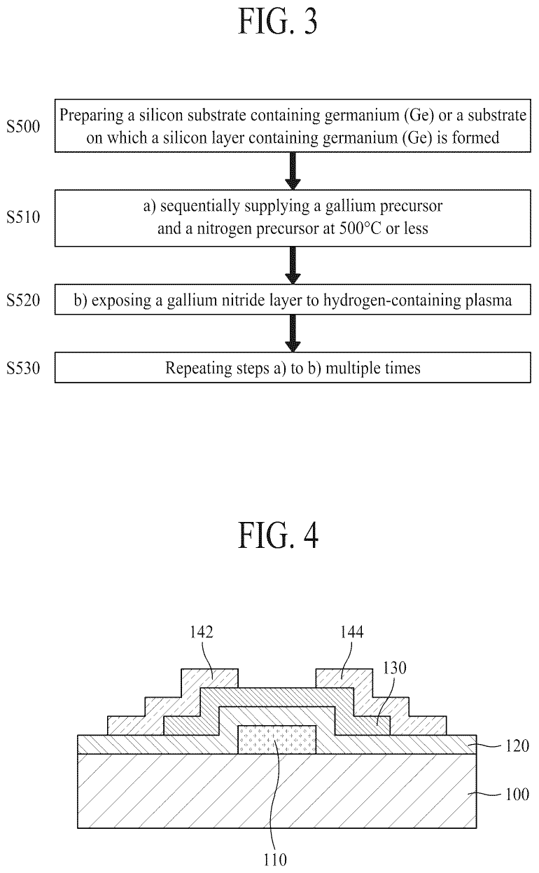

FIG. 3 is a diagram illustrating a method of manufacturing a semiconductor device according to another embodiment of the present invention.

The method of manufacturing a semiconductor device according to FIG. 3 may be used to manufacture a transistor. The method comprises preparing a silicon substrate containing germanium (Ge) or a substrate on which a silicon layer containing germanium (Ge) is formed (S500), a) sequentially supplying a gallium precursor and a nitrogen precursor at 500° C. or less on the substrate to form a gallium nitride layer (S510), and b) exposing the gallium nitride layer to hydrogen-containing plasma (S520). Steps a) to b) may be repeated multiple times (S530). Alternatively, in step S530, only step a) may be repeated or only step b) may be repeated.

In addition, a step of forming an additional pure silicon layer may be added between the silicon substrate containing germanium (Ge) or the substrate with the silicon layer containing germanium (Ge) and a gallium nitride (GaN) layer. The step of forming the pure silicon layer may include an epitaxy growth (Epi) method of silicon (Si).

In the step of supplying a reactant gas containing a nitrogen precursor, a hydrogen-containing plasma may be formed.

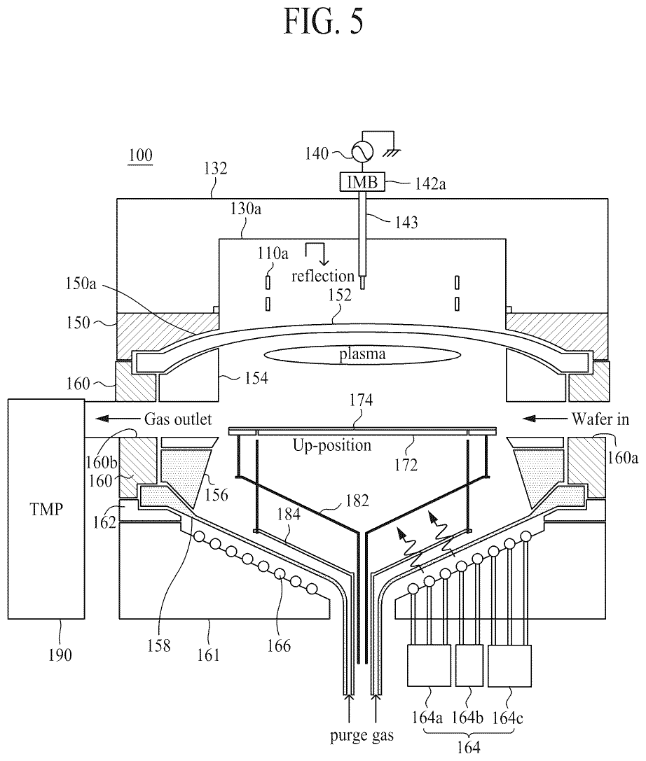

The step (S500) of preparing the silicon substrate containing germanium (Ge) or the substrate with the silicon layer containing germanium (Ge) may include a process of carrying the substrate into a process space of the chamber 160 of FIG. 5 to be described later. The substrate carried into the process space may be loaded on the substrate support 172 of FIG. 5 to be described later. Here, the substrate may be one of a silicon substrate containing germanium (Ge), a substrate on which a silicon layer containing germanium (Ge) is formed, a sapphire substrate, a sapphire substrate on which a silicon layer containing germanium (Ge) is formed, a glass substrate, a glass substrate on which a silicon layer containing germanium (Ge) is formed, and a silicon wafer.

In addition, the step of carrying the substrate (S500) may be performed by carrying a substrate having a predetermined functional layer. For example, in the stage of preparing and carrying the substrate (S500), a substrate with a gate electrode disposed on an upper surface of the substrate and a gate insulating film disposed on the gate electrode to cover the gate electrode may be used. Alternatively, a substrate with an encapsulation layer, drain electrode and a source electrode is used.

Here, the substrate support 172 of FIG. 5, which will be described later, may be equipped with an electrostatic chuck to adsorb the substrate, or may be equipped with a vacuum adsorption means or mechanical fixing element.

The step of a) sequentially supplying a gallium precursor and a nitrogen precursor at 500° C. or less on the substrate to form a gallium nitride layer (S510) includes forming a gallium nitride layer on the substrate carried into the process space of the chamber 160 of FIG. 5 to be described later. Here, the gallium nitride (GaN) layer may consist of at least a part of an active layer of a thin film transistor (TFT) used as a switching circuit in a semiconductor device or a display device. For example, the gallium nitride layer may form a channel region between the gate electrode and the source/drain electrode.

In an embodiment of the present invention, the step of a) sequentially supplying a gallium precursor and a nitrogen precursor at 500° C. or less on the substrate to form a gallium nitride layer (S510) may be performed in a low temperature process. That is, the step of a) sequentially supplying a gallium precursor and a nitrogen precursor at 500° C. or less on the substrate to form a gallium nitride layer (S510) may be performed by controlling the process space of the chamber 160 to a temperature of 50° C. or more and 500° C. or less.

The gallium nitride layer may be formed by an atomic layer growth (ALG) process or an atomic layer deposition (ALD) process at a low temperature of 50° C. to 600° C., which will be described in more detail below.

The gallium precursor may include trimethyl gallium (TMGa) gas containing gallium as a main component. The source gas containing gallium precursor is sprayed on the substrate to adsorb or deposit on the substrate.

A step of supplying a dopant gas on the substrate may be performed simultaneously with supplying the gallium precursor or after supplying the gallium precursor. As described above, the gallium nitride layer forms at least a part of the active layer, and the active layer may be formed of a p-type active layer or an n-type active layer depending on the type of the active layer. Therefore, a step of supplying a p-type dopant gas or an n-type dopant gas on the substrate may be performed at the same time as or after supplying a gallium precursor, that is, a source gas. The dopant gas may be supplied through at least one of a first gas supply path and a second gas supply path, wherein the p-type dopant gas may include bis-cyclopentadienyl magnesium (Cp2Mg) gas, and the n-type dopant gas may include diisopropylaminosilane (DIPAS).

In this way, a p-type gallium nitride layer or an n-type gallium nitride layer can be formed by supplying the p-type dopant gas or the n-type dopant gas after supplying a gallium precursor and before spraying a nitrogen precursor. The gallium precursor may be supplied, the purge gas may be supplied, the dopant (p-type dopant or n-type dopant) gas may be supplied, the purge gas may be supplied, the nitrogen precursor may be supplied, and the purge gas may be supplied. Alternatively, a dopant (p-type dopant or n-type dopant) gas may be supplied at the same time as the gallium precursor is supplied, a purge gas may be supplied, a nitrogen precursor may be supplied, and a purge gas may be supplied.

While sequentially supplying the gallium precursor and the nitrogen precursor, a purge gas can be supplied so that gas is discharged to an outside of the chamber 160 and source gas and reactant gas remaining in the process space of the chamber 160 can be removed. The purge gas may be an inert gas, for example, argon (Ar) gas.

After forming the gallium nitride layer, the gallium nitride layer may be exposed to hydrogen (H₂)-containing plasma. At this time, hydrogen gas may be activated and supplied.

When supplying the reactant gas, which is a nitrogen gas, the reactant gas may be activated and supplied to effectively react the nitrogen component with the gallium component. The nitrogen-containing gas can be activated to nitrogen radicals to react with the gallium component, and a gallium nitride layer can be formed on the substrate at a lower process temperature. That is, when reactant gas is activated and supplied onto the substrate, it can be performed by controlling the chamber for forming the gallium nitride layer at a low temperature.

After supplying a reactant gas to form a gallium nitride layer or after exposing the gallium nitride layer to hydrogen-containing plasma, an inert gas, such as argon (Ar) gas, may be supplied to purge the remaining gas in the chamber 160.

The amorphous gallium nitride layer may be crystallized by hydrogen (H₂) plasma. When a gallium nitride layer is formed simply by supplying source gas and reactant gas, the gallium nitride layer may be deposited on the substrate in an amorphous state. As in the embodiment of this invention, when hydrogen-containing gas is activated and supplied to the substrate after purging the reactant gas, the amorphous gallium nitride layer can be crystallized to have a polycrystalline or single crystal structure. In addition to hydrogen gas, inert gases Ar and He gases can also be used.

In addition, if the temperature inside the chamber 160 or the temperature of the substrate is low, for example, a gallium nitride layer can be formed at a low temperature of 500° C. or less. In addition, it is possible to effectively remove impurities remaining inside the chamber 160 or impurities contained in the gallium nitride layer by forming hydrogen plasma on the substrate.

Here, a) sequentially supplying gallium precursor and nitrogen precursor at 500° C. or less (S510) and b) exposing the gallium nitride layer to hydrogen-containing plasma (S520) may be repeated multiple times to form the desired thickness and crystallization of the gallium nitride layer. Or, after a) step is repeated multiple times, b) step is repeated.

FIG. 4 is a diagram schematically illustrating a transistor manufactured according to an embodiment of the present invention. The embodiment relates to a bottom gate structure, but, the present invention may also include a top gate structure. FIG. 4 shows a transistor including a gallium nitride layer prepared by the manufacturing method according to FIG. 3 as an active layer 130.

According to FIG. 4, a transistor according to an embodiment of this invention includes a gate electrode 110, a source electrode 142 and a drain electrode 144 horizontally spaced apart from each other and disposed over or under the gate electrode 110, an active layer 130 disposed between the gate electrode 110 and the source electrode 142 and between the gate electrode 110 and the drain electrode 144, and a gate insulating layer 120 disposed between the gate electrode 110 and the active layer 130.

At least a portion of the active layer 130 is formed of a gallium nitride layer.

Here, the transistor according to an embodiment of this invention may be a bottom gate type transistor which includes a gate electrode 110 formed on a substrate 100, a gate insulating film 120 formed on the gate electrode 110, an active layer 130 formed on the gate insulating film 120, and a source electrode 142 and a drain electrode 144 formed apart from each other and disposed on the active layer 130. However, the transistor according to an embodiment of this invention includes a top gate type transistor with the gate electrode 110 disposed over the active layer 130.

Here, the substrate 100 may include various substrates to form a gallium nitride (GaN) layer. For example, the substrate may be one of a silicon substrate containing germanium (Ge), a substrate on which a silicon layer containing germanium (Ge) is formed, a sapphire substrate, a sapphire substrate on which a silicon layer containing germanium (Ge) is formed, a glass substrate, a glass substrate on which a silicon layer containing germanium (Ge) is formed, and a silicon wafer. In addition, various substrates such as a transparent substrate or a flexible substrate may be used as the substrate 100.

The gate electrode 110, the source electrode 142, and the drain electrode 144 may be formed using conductive materials, such as aluminum (Al), neodymium (Nd), silver (Ag), chromium (Cr), titanium (Ti), tantalum (Ta), molybdenum (Mo), and copper (Cu), or an alloy. In addition, the gate electrode 110 may be formed of a single layer or a multilayer consisting of a plurality of metal layers. For example, the gate electrode 110 may be formed as a double layer including a metal layer such as chromium (Cr), titanium (Ti), tantalum (Ta), and molybdenum (Mo) with excellent physicochemical properties, and a metal layer such as aluminum (Al), silver (Ag) and copper (Cu) with low specific resistance.

The gate insulating layer 120 is formed on the gate electrode 110. That is, the gate insulating layer 120 may be formed on an upper surface of the substrate 100 and an upper portion and a side portion of the gate electrode 110. The gate insulating film 120 may be formed of one or more of silicon oxide (SiO₂), silicon nitride (SiN), high-K dielectric, and aluminum oxide (Al₂O₃) with excellent adhesion to metal materials and excellent insulation resistance. Here, the high-K dielectric is a dielectric with a higher dielectric rate than silicon oxide (SiO₂), and may include hafnium oxide (HfO₂), zirconium oxide (ZrO₂), etc.

The active layer 130 is formed on the gate insulating layer 120, and at least a portion of the active layer 130 is formed to overlap the gate electrode 110. The active layer 130 may include a gallium nitride layer. As described above, the gallium nitride layer may include loading a substrate into the process space of the chamber and forming a gallium nitride layer on the substrate. The forming the gallium nitride layer may include supplying a source gas containing gallium on the substrate, supplying a reactant gas containing nitrogen on the substrate, and activating and supplying a post-treatment gas containing hydrogen on the substrate supplied with the reactant gas.

Although not illustrated in FIG. 4, such a gallium nitride layer may be formed directly on the gate insulating film 120, but a buffer layer may be formed on the gate insulating film and a gallium nitride layer may be formed on the buffer layer. Here, the buffer layer is a layer formed before the gallium nitride layer, and may be a seed layer that helps the gallium nitride layer crystallize more effectively. That is, when forming the gallium nitride layer, the buffer layer may be a seed layer that facilitates crystallization of the gallium nitride layer. The buffer layer may be formed of an aluminum nitride (AlN) layer, and may be formed by various layer formation processes such as an atomic layer deposition method or a chemical vapor deposition method.

The source electrode 142 and the drain electrode 144 are formed above the active layer 130, that is, the gallium nitride layer, and may partially overlap the gate electrode 110. The source electrode 142 and the drain electrode 144 are spaced apart from each other. The source electrode 142 and the drain electrode 144 may be formed by the same process using the same material and may be formed using a conductive material, such as aluminum (Al), neodymium (Nd), silver (Ag), chromium (Cr), titanium (Ti), tantalum (Ta), and molybdenum (Mo), or an alloy thereof. The source electrode 142 and the drain electrode 144 may be formed of the same material as the gate electrode 110, but may be formed of a different material. In addition, the source electrode 142 and the drain electrode 144 may be formed of a single layer or multiple layers of a plurality of metal layers, respectively.

In addition, it may include a step of forming an additional pure silicon layer on a silicon substrate containing germanium (Ge) or a substrate with a silicon layer containing germanium (Ge). This step may include an epitaxy growth (Epi) method of silicon (Si).

LED devices can include light emission parts of red, green, and blue, of which green and blue emissions can be made of gallium nitride (GaN), and red emission can be made of gallium arsenide (GaAs).

FIG. 5 is a diagram schematically illustrating a deposition apparatus according to an embodiment of the present invention.

Referring to FIG. 5, an atomic layer deposition apparatus according to the embodiment of this invention is a device for depositing a gallium nitride layer and includes an upper dome 152 and a lower dome 158. Process gas, that is, source gas and reactant gas may be supplied into the upper dome 152, respectively, and process gas, that is, source gas and reactant gas may be exhausted from the upper dome 152. The source gas and the reactant gas may be supplied through a gas injector. The gas injector includes one or more injectors, and may inject process gas into the process space by one or more injectors. A process space may be located under the upper dome 152. By supplying purge gas to the lower dome 158 and process gas to the upper dome 152, the deposition of abnormal layers in the lower dome 158 can be suppressed by preventing the process gas from flowing to the lower dome 158. In addition, a uniform plasma may be formed to form a uniform layer without rotating the substrate 174.

In addition, gallium nitride (GaN) and gallium arsenide (GaAs) of this process can be formed as plasma enhanced ALD (PEALD) devices by employing an inductively coupled plasma source.

The atomic layer deposition device equipped with the upper dome 152 and the lower dome 158 is equipped with liners 154, 156 to prevent unnecessary layer deposition on the inner wall of the chamber 160. The liners 154 and 156 may be periodically replaced or cleaned.

A plurality of lamp heaters 166 disposed under the lower dome 158 may be ring-shaped lamp heaters. A plurality of lamp heaters 166 may independently control power to uniformly heat the substrate 174.

The high vacuum pump 190 made of a turbomolecular pump (TMP) connected to the exhaust port of the chamber 160 maintains a base vacuum inside the chamber 160, thereby forming a stable plasma at a pressure of several torr or less during the process.

The atomic layer deposition (ALD) device of this invention can reduce performance degradation caused by infrared heating of the antenna 110a forming the inductively coupled plasma placed on the upper dome 152 and provide infrared reflected from the electromagnetic wave shielding housing 130a to the substrate 174 again, thereby forming an uniform layer on the substrate 174 at high speed.

According to FIG. 5, the atomic layer deposition (ALD) device 100 according to an embodiment of this invention includes a chamber 160 with sidewalls; a substrate support 172 provided inside the chamber and supporting the substrate; an upper dome 152 covering the upper surface of the chamber 160 and made of a transparent dielectric material; an antenna 110a placed above the upper dome 152 to form inductively coupled plasma; and the electromagnetic wave shielding housing 130a placed to surround the antenna 110a. The electromagnetic wave shielding housing 130a may be heated by a heater.

The antenna 110a includes two one-turn unit antennas, and the two one-turn unit antennas can be connected in parallel to the RF power source 140.

The step of generating hydrogen plasma after the step of supplying reactant gas and the step of generating plasma between the source gas supplying step and the reactant gas supplying step may be performed by the antenna 110a.

The source gas and reactant gas may be injected into the process space within the upper dome 152 and the lower dome 158 by an injector (not shown). The source gas and reactant gas may be supplied in the upper dome 152 direction or horizontal direction by the injector and injected into the chamber 160.

The chamber 160 is formed of a conductor, the inner space of the chamber 160 may be cylindrical, and the outer shape of the chamber 160 may be a rectangular parallelepiped shape. The chamber 160 may be cooled by cooling water. The chamber 160, the upper dome 152, and the lower dome 158 are combined to provide a sealed space.

A substrate inlet 160a may be provided on one side of the chamber 160 and an exhaust port 160b may be provided on the other side of the chamber 160 facing the substrate inlet 160a. The exhaust port 160b may be connected to the high vacuum pump 190. The high vacuum pump 190 may be a turbomolecular pump. The high vacuum pump 190 helps to maintain a low base pressure and maintain a pressure of several torr or less even during the process. An upper surface of the exhaust port 160b may be equal to or lower than an upper surface of the substrate inlet 160a.

The upper dome 152 may be made of quartz, sapphire, or ceramic as a transparent dielectric. The upper dome 152 may be formed of a ceramic material. Ceramic materials have better corrosion resistance than quartz.

The upper dome 152 may be inserted into a jaw formed on the upper surface of the chamber 160 to be coupled to the chamber 160. The coupling portion of the upper dome 152 coupled to the chamber 160 for vacuum sealing may have a washer shape. The upper dome 152 may have an arc shape or an oval shape. The upper dome 152 may transmit infrared rays incident from the lower portion.

Infrared rays reflected from the electromagnetic wave shielding housing 130a may pass through the upper dome 152 and may enter the substrate 174.

The lower dome 158 is a transparent dielectric and may be formed of quartz or sapphire. The lower dome 158 may include a washer-shaped coupling part coupled to a jaw formed on the lower surface of the chamber 160, a funnel-shaped lower dome body extending below the coupling part, and a cylindrical pipe extending downward from the center of the lower dome body. The lower dome 158 may be inserted into a jaw formed on the lower surface of the chamber 160 and coupled to the chamber 160. The coupling portion of the lower dome 158 coupled to the chamber 160 for vacuum sealing may have a washer shape.

The drive shaft of a first lifter 184 and the drive shaft of a second lifter 182 may be inserted and disposed in the cylindrical pipe of the lower dome 158. The purge gas supplied through the lower dome 158 may be supplied through a flow path. The flow path may be a cylindrical pipe of the lower dome 158. The purge gas may be an inert gas such as argon.

A upper liner 154 may be made of a transparent dielectric material. For example, the upper liner 154 may be made of quartz, alumina, sapphire, or aluminum nitride. The upper liner 154 may be made of a material that suppresses deposition of an abnormal layer.

A heat insulating portion 162 may be disposed between the lower surface of the chamber 160 and a reflector 161 and may have a ring shape. The heat insulating part 162 may reduce heat transfer from the heated reflector 161 to the chamber 160. The heat insulating portion 162 may be made of a ceramic material. The upper surface of the heat insulating portion 162 may have a jaw. The jaw of the heat insulating portion 162 and the jaw of the lower surface of the chamber 160 can accommodate the washer-shaped coupling part of the lower dome 158 and vacuum seal inside.

A concentric lamp heater 166 may include a plurality of concentric ring-shaped lamp heaters and may be connected to a power source 164. A plurality of the concentric ring-shaped lamp heaters 166 are arranged at regular intervals along the slope of the lower dome 158, and the concentric lamp heater 166 can be divided into three groups to receive power independently of each other. The concentric ring-shaped lamp heater 166 may be inserted into and aligned with a ring-shaped groove formed on an inclined surface of the reflector 161.

For example, the concentric lamp heater 166 may be a halogen lamp heater and eight of the concentric lamp heaters 166 may be applied. The lower three lamp heaters may form a first group, the middle two lamp heaters may form a second group, and the upper three lamp heaters may form a third group. The first group may be connected to a first power source 164a, the second group may be connected to a second power source 164b, and the third group may be connected to a third power source 164c. The first to third power sources 164a to 164c may be independently controlled for uniform heating of the substrate.

The RF power source 140 may supply RF power to the antenna 110a through an impedance matching box (IMB) 142a and a power supply line 143. The antenna 110a through which RF current flows has a sufficient cross-sectional area for high current, and it is desirable to form a closed loop to form a sufficient magnetic flux. The antenna 110a may use a vertically erected strip line to minimize an increase in resistance due to heating caused by absorbing infrared rays incident from the upper or lower part thereof. The antenna 110a provides high light transmittance with respect to infrared rays.

In addition, the antenna 110a may be coated with gold (Au) or silver (Ag) to increase infrared reflection. In addition, in order to secure sufficient magnetic flux, a two-layer structure of antenna 110a may be used.

The lower dome 158 covers the lower surface of the chamber 160 and is formed of a transparent dielectric material, and may have the same curvature as the upper dome 152. The lamp heater 166 may be disposed on a lower surface of the lower dome 158. The reflector 161 may be disposed on a lower surface of the lamp heater 166.

In addition, a controller (not shown) for controlling the RF power source 140 may be further included. Here, for example, a source gas supply path (not shown) and a reactant gas supply path (not shown) for supplying raw material gas may be formed separately.

Meanwhile, a silicon substrate containing germanium (Ge) may be loaded in the chamber 160 for a layer formation process on the substrate support 172. The substrate 100 may include various substrates to form a gallium nitride (GaN) layer. For example, the substrate may be one of a silicon substrate containing germanium (Ge), a substrate on which a silicon layer containing germanium (Ge) is formed, a sapphire substrate, a sapphire substrate on which a silicon layer containing germanium (Ge) is formed, a glass substrate, a glass substrate on which a silicon layer containing germanium (Ge) is formed, and a silicon wafer.

The substrate support 172 may be equipped with an electrostatic chuck to adsorb the substrate 172 by electrostatic force, or may be equipped with a vacuum adsorption means or mechanical fixing element.

The clamp 150 may be disposed to cover the edge of the upper dome 152. The clamp 150 is formed of a conductor and may be cooled by cooling water. The lower surface of the clamp 150 may have a jaw to be coupled to the washer-shaped coupling part of the upper dome 152, and may include a curved part 150a to cover a part of the curved part of the upper dome 152. The curved part 150a of the clamp 150 may be gold-plated to reflect infrared rays. An inner diameter of the clamp 150 may be substantially the same as an inner diameter of the upper liner 154. In addition, the inner diameter of the clamp 150 may be the same as the diameter of the antenna housing 130a.

The chamber housing 132 may be disposed on the clamp 150 and may be disposed to cover the antenna housing 130a.

Meanwhile, it can be configured that gas containing gallium (Ga) can be supplied as a source gas, and gas containing nitrogen (N) can be supplied as a reactant gas. Here, a source gas, for example, a gas containing gallium, may include trimethyl gallium (TMGa) gas, and a reactant gas, for example, a gas containing nitrogen, may include ammonia (NH₃) gas.

Hereinabove, the embodiments of the present invention have been described in more detail with reference to the accompanying drawings, but the present invention is not limited to the embodiments and may be variously modified within a range which does not depart from the technical spirit of the present invention. Therefore, it should be understood that the embodiments described above are exemplary from every aspect and are not restrictive. It should be construed that the scope of the present invention is defined by the below-described claims instead of the detailed description, and the meanings and scope of the claims and all variations or modified forms inferred from their equivalent concepts are included in the scope of the present invention.

1. A method of manufacturing a semiconductor device including a process of forming at least one gallium nitride layer or at least one gallium arsenide layer among an undoped gallium nitride layer, an undoped gallium arsenide layer, an N-type gallium nitride layer, an N-type gallium arsenide layer, an active layer, a P-type gallium nitride layer, and a P-type gallium arsenide layer on a silicon substrate containing germanium or a substrate on which a silicon layer containing germanium is formed, the process of forming the at least one gallium nitride layer or the at least one gallium arsenide layer comprises:
a) sequentially supplying i) a gallium precursor and ii) a nitrogen precursor or an arsenide precursor at 500° C. or less to form a gallium nitride layer or a gallium arsenide layer on the silicon substrate or the substrate, and
b) exposing the gallium nitride layer or the gallium arsenide layer to hydrogen-containing plasma,
wherein the a) and the b) are repeated multiple times.

2. A method of manufacturing a semiconductor device including a process of forming a gallium nitride layer or an arsenide layer on a silicon substrate containing germanium or a substrate on which a silicon layer containing germanium is formed,
the process of forming the gallium nitride layer or the gallium arsenide layer comprises sequentially supplying i) a gallium precursor and ii) a nitrogen precursor or an arsenide precursor into a chamber, and
wherein the sequentially supplying i) the gallium precursor and ii) the nitrogen precursor or the arsenide precursor into the chamber comprises:
a) flowing the gallium precursor into the chamber at 500° C. or less through a gas injector, and
b) flowing the nitrogen precursor or the arsenide precursor through the gas injector to form the gallium nitride layer or the gallium arsenide layer on the silicon substrate or the substrate.

3. A method of manufacturing a semiconductor device including a process of forming at least one gallium nitride layer or at least one gallium arsenide layer among an undoped gallium nitride layer, an undoped gallium arsenide layer, an N-type gallium nitride layer, an N-type gallium arsenide layer, an active layer, a P-type gallium nitride layer, and a P-type gallium arsenide layer on a silicon substrate containing germanium or a substrate on which a silicon layer containing germanium is formed,
the process of forming at least one gallium nitride layer or at least one gallium arsenide layer comprises sequentially supplying i) a gallium precursor and ii) a nitrogen precursor or an arsenide precursor at 500° C. or less to form a gallium nitride layer or a gallium arsenide layer on the silicon substrate or the substrate,
wherein plasma is generated when supplying the nitrogen precursor or the arsenide precursor.

4. The method of manufacturing a semiconductor device of claim 2, further comprising exposing the gallium nitride layer or the gallium arsenide layer to hydrogen-containing plasma after forming the gallium nitride layer or the gallium arsenide layer.

5. The method of manufacturing a semiconductor device of claim 1, wherein the process of forming the N-type gallium nitride layer or the N-type gallium arsenide layer further comprises supplying a silicon precursor,
wherein the process of forming the active layer further comprises supplying an indium precursor, and
wherein the process of forming the P-type gallium nitride layer or the P-type gallium arsenide layer further comprises supplying a magnesium precursor.

6. The method of manufacturing a semiconductor device of claim 1, further comprising generating hydrogen-containing plasma between supplying the gallium precursor and supplying the nitrogen precursor or the arsenide precursor.

7. The method of manufacturing a semiconductor device of claim 1, further comprising exposing the silicon substrate or the substrate to a gas containing at least one of fluorine and chlorine to remove oxide and impurities on the silicon substrate or the substrate, before supplying the gallium precursor.

8. The method of manufacturing a semiconductor device of claim 7, wherein removing oxide and impurities on the silicon substrate or the substrate is performed in a same chamber or system as a chamber or system for forming the gallium nitride layer or the gallium arsenide layer.

9. The method of manufacturing a semiconductor device of claim 1, further comprising forming an encapsulation layer to prevent moisture or oxygen from penetrating through the silicon substrate or the substrate.

10. The method of manufacturing a semiconductor device of claim 1, further comprising forming a pure silicon layer on the silicon substrate or the substrate.

11. The method of manufacturing a semiconductor device of claim 1, further comprising
loading at least one substrate on a substrate support in an atomic layer deposition chamber including a gas injector, the at least one substrate including the silicon substrate containing germanium or the substrate on which a silicon layer containing germanium is formed; and
flowing a purge gas for purging the gallium precursor into the atomic layer deposition chamber between supplying the gallium precursor and supplying the nitrogen precursor or the arsenide precursor.

12. The method of manufacturing a semiconductor device of claim 3, further comprising exposing the gallium nitride layer or the gallium arsenide layer to hydrogen-containing plasma after forming the gallium nitride layer or the gallium arsenide layer.

13. The method of manufacturing a semiconductor device of claim 3, wherein the process of forming the N-type gallium nitride layer or the N-type gallium arsenide layer further comprises supplying a silicon precursor,
wherein the process of forming the active layer further comprises supplying an indium precursor, and
wherein the process of forming the P-type gallium nitride layer or the P-type gallium arsenide layer further comprises supplying a magnesium precursor.

14. The method of manufacturing a semiconductor device of claim 2, further comprising generating hydrogen-containing plasma between supplying the gallium precursor and supplying the nitrogen precursor or the arsenide precursor.

15. The method of manufacturing a semiconductor device of claim 3, further comprising generating hydrogen-containing plasma between supplying the gallium precursor and supplying the nitrogen precursor or the arsenide precursor.

16. The method of manufacturing a semiconductor device of claim 2, further comprising forming an encapsulation layer to prevent moisture or oxygen from penetrating through the silicon substrate or the substrate.

17. The method of manufacturing a semiconductor device of claim 3, further comprising forming an encapsulation layer to prevent moisture or oxygen from penetrating through the silicon substrate or the substrate.

18. The method of manufacturing a semiconductor device of claim 2, further comprising forming a pure silicon layer on the silicon substrate or the substrate.

19. The method of manufacturing a semiconductor device of claim 3, further comprising forming a pure silicon layer on the silicon substrate or the substrate.

20. The method of manufacturing a semiconductor device of claim 3, further comprising loading at least one substrate on a substrate support in an atomic layer deposition chamber including a gas injector, the at least one substrate including the silicon substrate containing germanium or the substrate on which a silicon layer containing germanium is formed; and
flowing a purge gas for purging the gallium precursor into the atomic layer deposition chamber between supplying the gallium precursor and supplying the nitrogen precursor or the arsenide precursor.
